(19) United States
(12) Patent Application Publication
(10) Pub. No.: US 2019/0068429 A1
(43) Pub. Date: Feb. 28, 2019

(54) METHOD AND APPARATUS WITH COMMON DIGITAL PRE-DISTORTION COMPONENT FOR MULTIPLE TRANSMIT CHAINS

(71) Applicant: QUALCOMM Incorporated, San Diego, CA (US)

(72) Inventors: Ariel Sagi, Haifa (IL); Igor Gutman, Ramat Gan (IL); Alecsander Eitan, Haifa (IL)

(21) Appl. No.: 15/688,734

(22) Filed: Aug. 28, 2017

(51) Int. Cl. H04L 27/36; H03F 1/32

(52) U.S. Cl. CPC H04L 27/367; H04N 19/91; H03F 1/3241

(57) ABSTRACT

Certain aspects of the present disclosure are directed to digital predistortion (DPD) for use with a multi-chain wireless transmitter. In various examples described herein, the multi-chain transmitter is configured to use a single common DPD device or module for all transmit chains and to adjust the bias voltages of the power amplifiers of the separate transmit chains to operate at substantially the same backoff so the distortion to the corresponding output signals is similar. Since the distortion of the output of the different chains is similar, a single common predistortion may be applied using the single DPD device to a signal to be transmitted. Techniques are also described for calibrating the predistortion coefficients of the DPD to optimize (or otherwise set) the amount of distortion reduction to be achieved. The predistortion coefficients for the single DPD may be set or calibrated based on a particular directionality needed for beamforming.

### TECHNICAL FIELD

The invention relates generally to wireless communications systems and, more particularly, to methods and apparatus for digital pre-distortion (DPD).

### BACKGROUND

A signal transmitting device, such as those used in wireless communications, typically includes a power amplifier (PA) for amplifying an RF signal with sufficient power for wireless transmission to remote devices via one or more antennas. Although the PAs may be fairly linear at lower amplification levels far from saturation, PAs can become significantly non-linear at or near saturation. For applications where power efficiency is not crucial, non-linearity can be avoided by backing off the PA from saturation into a linear realm. For wireless communications, power efficiency is often quite important, and so a better solution is needed.

### SUMMARY

Certain aspects of the present disclosure provide an apparatus for wireless communications. The apparatus comprises a processing system configured to: configure a set of power amplifiers of a set of transmit chains such that each power amplifier is to be operated with a common amount of backoff to amplify a transmit signal, and generate a predistorted signal for the set of transmit chains based on the common amount of backoff; and an interface configured to output the predistorted signal to the set of transmit chains for transmission of the transmit signal.

Certain aspects of the present disclosure provide a method for wireless communications comprising configuring a set of power amplifiers of a set of transmit chains such that each power amplifier is to be operated with a common amount of backoff to amplify a transmit signal; generating a predistorted signal for the set of transmit chains based on the common amount of backoff; and outputting the predistorted signal to the set of transmit chains for transmission of the transmit signal.

Certain aspects of the present disclosure provide an apparatus for wireless communications. The apparatus comprises means for configuring a set of power amplifiers of a set of transmit chains such that each power amplifier is to be operated with a common amount of backoff to amplify a transmit signal; means for generating a predistorted signal for the set of transmit chains based on the common amount of backoff; and means for outputting the predistorted signal to the set of transmit chains for transmission of the transmit signal.

Certain aspects of the present disclosure provide a computer readable medium having instructions stored thereon for configuring a set of power amplifiers of a set of transmit chains such that each power amplifier is to be operated with a common amount of backoff to amplify a transmit signal; generating a predistorted signal for the set of transmit chains based on the common amount of backoff; and outputting the predistorted signal to the set of transmit chains for transmission of the transmit signal.

Certain aspects of the present disclosure provide a wireless node. The wireless node comprises: a transmitter including a set of transmit chains having a set of power amplifiers, respectively; and a processing system configured to: configure the set of power amplifiers of the set of transmit chains such that each power amplifier is to be operated with a common amount of backoff to amplify a transmit signal; and generate a predistorted signal for the set of transmit chains based on the common amount of backoff; wherein the transmitter is configured to transmit the transmit signal.

Certain aspects of the present disclosure also provide various other apparatus, methods, and computer readable medium for performing the operations described herein.

### BRIEF DESCRIPTION OF THE DRAWINGS

FIG. 1 is a block diagram illustrating a single-chain transmitter equipped for digital predistortion (DPD) in accordance with aspects of the disclosure.

FIG. 2 is a block diagram illustrating a multiple-chain transmitter equipped for DPD in accordance with aspects of the disclosure.

FIG. 3 is a block diagram illustrating an exemplary multiple-chain transmitter equipped to use a single shared (i.e. common) DPD device, in accordance with aspects of the present disclosure.

FIG. 4 is a block diagram further illustrating the exemplary multiple-chain transmitter of FIG. 3, in accordance with aspects of the present disclosure.

FIG. 5 illustrates exemplary operations that may be performed by multiple-chain transmitter having a single DPD device, in accordance with aspects of the present disclosure.

FIG. 6 illustrates exemplary array-based calibration operations that may be performed to determine predistortion coefficients for use with a multiple-chain transmitter having a single DPD device, in accordance with aspects of the present disclosure.

FIG. 7 illustrates a lookup table for use with a multiple-chain transmitter having a single DPD device, in accordance with aspects of the present disclosure.

FIG. 8 illustrates an exemplary wireless communications network, in which aspects of the present disclosure may be implemented.

FIG. 9 illustrates an exemplary wireless device, in which aspects of the present disclosure may be implemented.

FIG. 10 illustrates exemplary operations that may be performed by the wireless device of FIG. 9, in accordance with aspects of the present disclosure.

FIG. 11 illustrates exemplary components that may be used to implement the operations of FIG. 10, in accordance with aspects of the present disclosure.

FIG. 12 illustrates other exemplary components that may be used to implement the operations of FIG. 10, in accordance with aspects of the present disclosure.

FIG. 13 illustrates exemplary computer readable medium instructions that may be used to control a transmitter to perform the operations of FIG. 10, in accordance with aspects of the present disclosure.

### DETAILED DESCRIPTION

Aspects of the present disclosure are directed to a radio-frequency (RF) transmitter having multiple transmit chains that employ digital predistortion (DPD), where a single common DPD module is shared by each of the transmit chains, i.e. each of the transmit chains receives predistorted signal from the common DPD. The use of the single common DPD module may help reduce circuit space and power consumption. Although the examples described herein are directed to open loop configurations (i.e. transmitters without feedback), aspects of the disclosure are also applicable to closed loop configurations where the output RF signal is sampled and fed back to the common DPD module (as a downconverted digital signal) for use in adaptively adjusting the DPD.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

Although particular aspects are described herein, many variations and permutations of these aspects fall within the scope of the disclosure. Although some benefits and advantages of the preferred aspects are mentioned, the scope of the disclosure is not intended to be limited to particular benefits, uses, or objectives. Rather, aspects of the disclosure are intended to be broadly applicable to different wireless technologies, system configurations, networks, and transmission protocols, some of which are illustrated by way of example in the figures and in the following description of the preferred aspects. The detailed description and drawings are merely illustrative of the disclosure rather than limiting, the scope of the disclosure being defined by the appended claims and equivalents thereof.

### Illustrative Examples without a Shared Common DPD Module

As discussed above, PAs can become significantly non-linear at or near saturation. For applications where power efficiency is not crucial, non-linearity can be avoided by backing off the PA from saturation into a linear realm. For wireless communications, power efficiency is often quite important, and so the input RF signal applied to a PA is set to a power level to drive the PA as close to saturation as possible.

Although driving the PA close to saturation improves power efficiency, it can also significantly distort the output signal from the PA due to the non-linearity of the PA, particularly when the input RF signal has a high peak-to-average-power ratio (PAPR) as is common in wireless communication. The resulting signal distortion has two main components: an in-band component and an out-of-band component. The in-band distortion can result in an increase in the error vector magnitude (EVM) of the signal component. The out-of-band distortion can result in pollution or interference to adjacent channel transmission, i.e., adjacent channel interference (ACI).

To operate the PA as close as possible to saturation for power efficiency purposes, while also reducing distortion of the output signal of the PA, a wireless transmitter may employ digital pre-distortion (DPD). With DPD, the nonlinear effects of the PA on the output signal are modeled, and an inverse distortion is applied to the baseband digital signal so that any subsequent distortion introduced by the non-linearity of the PA can be mostly cancelled out. In this manner, the degree of backoff from saturation can be significantly reduced as compared to transmitters without DPD, thus improving power efficiency without introducing significant signal distortion.

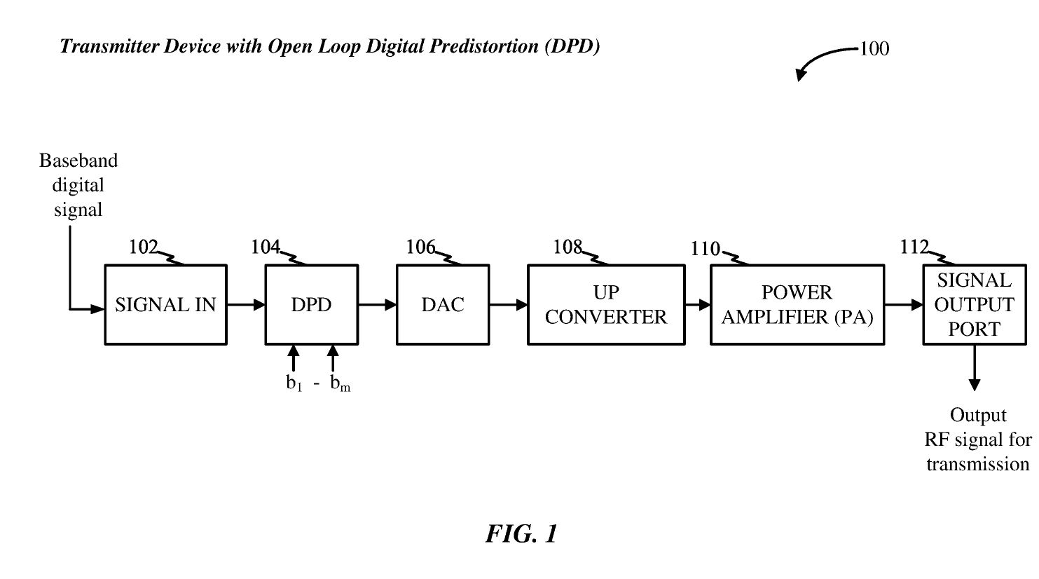

FIG. 1 is a block diagram of a transmitter 100 that includes a DPD device for reducing distortion in an output signal due to the non-linearity of a PA but does not exploit a shared DPD. In this example, the transmitter 100 includes a signal input port 102, a DPD 104, a digital-to-analog converter (DAC) 106, an upconverter 108, a PA 110, and a signal output port 112. The input port 102 receives a baseband digital signal (generated by other components of the wireless device in which the transmitter is installed). The DPD 104 applies a specified predistortion on the baseband digital signal using a set of predetermined predistortion coefficients b₁ to bₘ selected to reduce distortion of the final output RF signal due to the non-linearity of the PA 110. The DAC 106 converts the predistorted signal into an analog predistorted signal. The upconverter 108 frequency upconverts the analog signal to generate a radio frequency (RF) signal. The PA 110 amplifies the RF signal to generate the transmitter output signal, which is output using a signal output port 112 for transmission into free space via an antenna (not shown). As noted, for power efficiency purposes, the RF signal at the input of the PA 110 may be set to drive the PA 110 at only a few dB backoff. If uncorrected by the DPD 104, this would otherwise result in significant distortion in the RF output signal of the transmitter 100.

In the example of FIG. 1, the transmitter 100 is configured in an open loop DPD configuration. That is, the predistortion coefficients b₁ to bₘ are static or predetermined and are typically set in advance at a factory location. Although not shown, there are also closed loop (i.e. feedback) DPD configurations where the output signal of the PA is down-converted, sampled and analog-to-digital converted, and then applied to a DPD training module to dynamically or adaptively adjust the predistortion coefficients b₁ to bₘ based the current and/or historical characteristic of the PA output signal.

In some wireless devices, multiple transmit chains are employed, each having its own DPD, DAC, PA, etc., which operate in parallel. Although DPD may be efficient and effective in wireless transmitters that include relatively few transmit chains, issues can arise in devices that employ many such chains, often thirty-two or sixty-four, as may be used to achieve efficient beamforming for a desired antenna directivity.

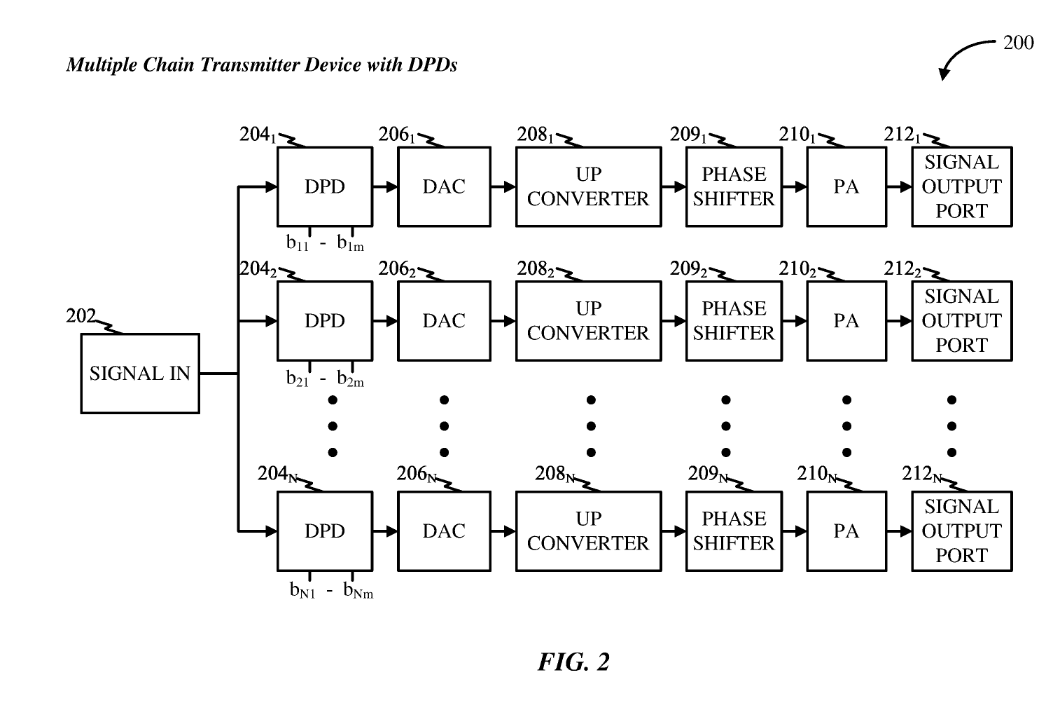

FIG. 2 is a block diagram of an exemplary multiple chain wireless transmitter 200 having N parallel transmit chains. The transmitter 200 includes a common input signal port 202 to receive the baseband digital signals for all of the N transmit chains. Each of the transmit chains includes a DPD (e.g., DPDs 204₁-204_{N}), a DAC (e.g., 206₁-206_{N}), an upconverter (e.g., upconverters 208₁-208_{N}), a phase-shifter (e.g., phase shifters 209₁-209_{N}), a PA (e.g., PAs 210₁-210_{N}), and an output signal port (e.g., output ports 214₁-214_{N}). The phase shifters 209₁-209_{N} are included in the multiple chain transmitter to achieve beamforming for the desired antenna directivity. The PAs may be biased using suitable bias signals. Although not shown in FIG. 2, the transmitter may also include a component for determining the transmit power for each of the transmit chains based on a selected antenna directivity (as specified by other components of the wireless device) and a component for determining the bias values for applying to the various PAs to set the transmit power for each chain to achieve the selected directivity.

In the example of FIG. 2, each of the transmit chains includes its own DPD. Separate DPDs are provided because each PA is operated at a different output signal power to achieve the desired beamforming for a particular antenna directivity. As a result, each of the PAs may distort the output signal in a different manner Thus, the DPDs 204₁-204_{N} receive different sets of predistortion coefficients b₁₁-b₁ₘ to b_{N1}-b_{Nm} to address the distinct distortion caused by the corresponding PA of the chain. Accordingly, because of the many transmit chains (e.g., sixty-four chains), the transmitter 200 uses an equal number DPDs, resulting in a transmitter that is complex, requires significant IC area, and may consume a substantial amount of power.

### Illustrative Examples using a Shared Common DPD Module

In various examples described herein below, a transmitter for a wireless device having multiple transmit chains is configured to: (1) use a single common (i.e. shared) DPD device or module for all transmit chains; and (2) adjust the bias voltages of the power amplifiers (PAs) of the separate transmit chains to operate at substantially the same backoff (BO) so the distortion to the corresponding output signals is similar. Techniques are also provided to determine or calibrate the predistortion coefficients for the common DPD to optimize (or otherwise set or specify) the amount of distortion reduction to be achieved.

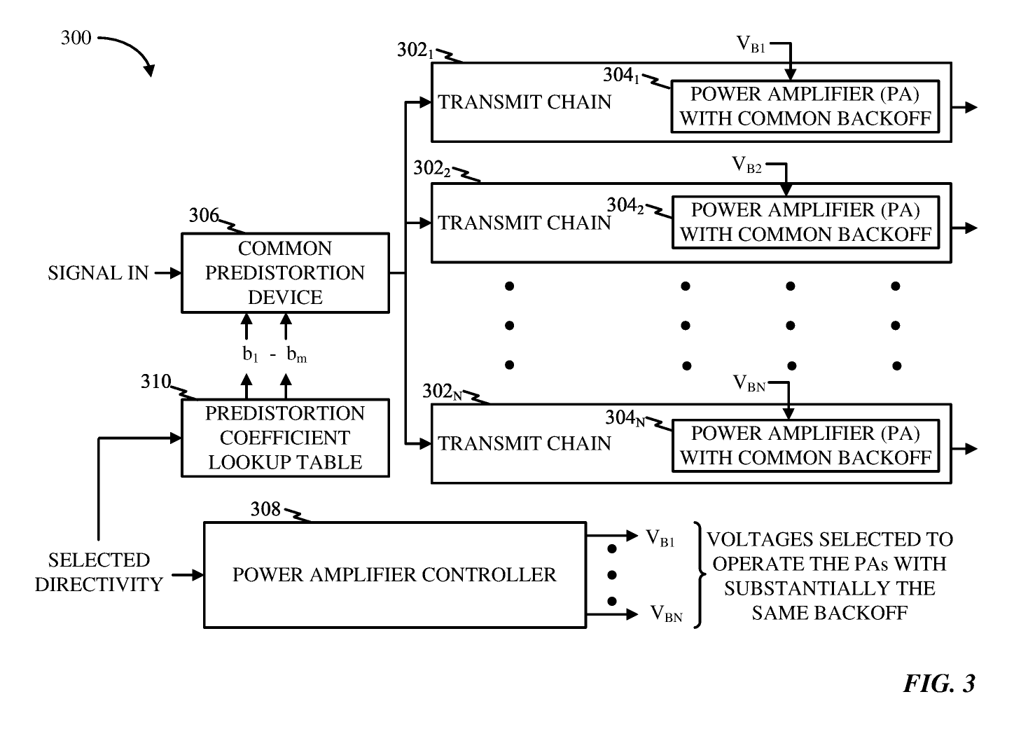

FIG. 3 is a high-level block diagram of an exemplary transmitter 300 for use in a wireless device and configured in accordance with aspects of the disclosure. FIG. 3 omits many of the details of a practical device, such as DACs, phase shifters and upconverters, which are included in more detailed examples, discussed below. The transmitter 300 includes a set of N transmit chains 302₁-302_{N}, each having a PA 304₁-304_{N} with common backoffs, i.e. with substantially the same backoff value. The PAs are configured to have substantially the same characteristics (e.g. the same non-linearity profile, etc.) and are typically identical devices. The PAs 304₁-304_{N} receive bias voltages V_{B1} to V_{BN}, respectively, which can be used to set or select the gain and saturation level of the PA. Additionally or alternatively, the output power of each PA can be controlled by the input power to the PA. This may be performed internally in the PA or, in some examples, by an additional device preceding the PA (not shown in FIG. 3). The transmitter 300 further includes a common predistortion device 306, which is “shared” by the transmit chains 302₁-302_{N} in the sense that each of the chains receives the same predistorted signal from the single predistortion device, rather than receiving different predistorted signals from separate predistortion devices.

The transmitter 300 further includes a power amplifier controller 308, which receives a selected directivity for the antenna array (not shown) of the device. The directivity value is determined or set by other components of the wireless device to achieve desired beamforming. Based on the directivity value, the power amplifier controller 308 determines the appropriate output signal powers of the transmit chains to achieve the selected directivity, then determines the appropriate bias voltages V_{B1} to V_{BN} to apply to the individual PAs 304₁-304_{N} to achieve the appropriate PA output power while operating with substantially the same backoff from saturation. That is, each PA is set to use a common backoff, although each may have a different gain. (This may be achieved by reducing PA bias according to the needed transmit power using techniques that may differ depending upon the particular choice of PA, i.e. bipolar junction transistor (BJT) vs. a metal-oxide semiconductor field-effect transistor (MOSFET).) The use of a common backoff differs from predecessor devices of the type discussed above in connection with FIG. 2, where the PAs of different transmit chains generally have different backoffs, set independently. The common backoff value of FIG. 3 is determined in advance as a design choice but, in some examples, might be instead determined by components of the transmitter 300 of by other components of the wireless device in which it is installed.

The bias voltages (V_{B1}-V_{B4}) are applied to the respective PAs (304₁-304₄) so that the PAs all operate with substantially the same (common) backoff. Since the same backoff is used for all of the PAs, it follows that the distortion of their respective output signals is likewise similar (since the PAs are identical devices, or at least have the same characteristics in terms of non-linearity relative to saturation). Since the distortion of the PAs is the same (or similar) when operating with the same backoff, each transmit chain need not have its own predistortion. Rather, the single common predistortion device 306 can be used, which applies predistortion to address the same (or similar) distortion of the PAs of each of the transmit chains. The particular coefficients (b₁ to bₘ) for applying to the predistortion device 306 to provide the appropriate predistortion for a particular directionality are determined or calibrated in advance (for the particular transmitter device) and stored in a predistortion coefficient lookup table 310. In use, the predistortion coefficient lookup table 310 receives the same beamforming directivity value received by the power amplifier controller 308, so that the table 310 may look up the appropriate coefficients to use for that directivity to provide the appropriate predistortion. The directivity is selected to improve the transmission of a transmit signal towards a target receiving device (e.g., the device expected to receive the transmit signal)

The predistortion coefficients (b₁ to bₘ) may be initially optimized (or otherwise set) based on the distortion correction appropriate for the highest transmitting transmit chain for the particular directionality (and for the chosen common backoff). That is, the particular predistortion profile to be used may be determined in advance for a particular beamforming direction to counter the distortion of the PA that needs to provide the strongest output for that directionality (and hence will likewise cause the greatest amount of distortion in the overall output transmission signal if not properly countered). It is noted that there might be some (relatively minor) variation in the particular non-linear distortion patterns of the various PAs, despite using the same backoff, since they are operating at different gains. Calibrating the predistortion coefficients (b₁ to bₘ) based on the PA that needs to provide the strongest gain for a particular directionality helps optimize the overall distortion correction, but other strategies might be used, such as by calibrating the predistortion coefficients based on an average peak power of the PAs.

The predistortion coefficients also may be set or calibrated in advance for each directivity of the antenna array in the factory to optimize or otherwise select the appropriate predistortion pattern. This may be done by configuring the transmitter to transmit with a particular directivity (relative to the orientation of the overall device in which the transmitter is installed) and with a particular backoff value (common to each PA), then having test equipment receive and analyze the transmitted signal to determine the distortion profile. The test equipment then adjusts the predistortion coefficients b₁ to bₘ for that particular direction to optimize or otherwise calibrate the predistortion profile to be used for that directionality (and for the chosen backoff).

So, for a WiFi example where communication is between an access point (AP) and a station (STA), the transmitter may be installed within the AP. The AP may be mounted to a test bench and controlled to transmit wireless signals in a particular direction (i.e. with a particular directivity). Test equipment is equipped to receive the transmitted signals and assess distortion within the received signal. Calibration components of the test equipment then adjust the predistortion coefficients b₁ to bₘ for that particular direction to reduce the distortion as much as possible. This array-based procedure is repeated for various different directions, with the optimal predistortion coefficients recorded for each of the tested directions. The information is stored within the AP so that its transmitter can use the optimal coefficients for any particular directionality during subsequent use of the AP.

The calibration procedure is repeated for all programmable beamforming directions to provide different predistortion coefficients for each programmable direction, which are stored in the predistortion coefficient lookup table 310 in the transmitter. Upon completion of the calibration procedure, the transmitter will then have the appropriate predistortion coefficients for all programmable directions of the antenna array.

An exemplary calibration procedure is discussed in further detail below.

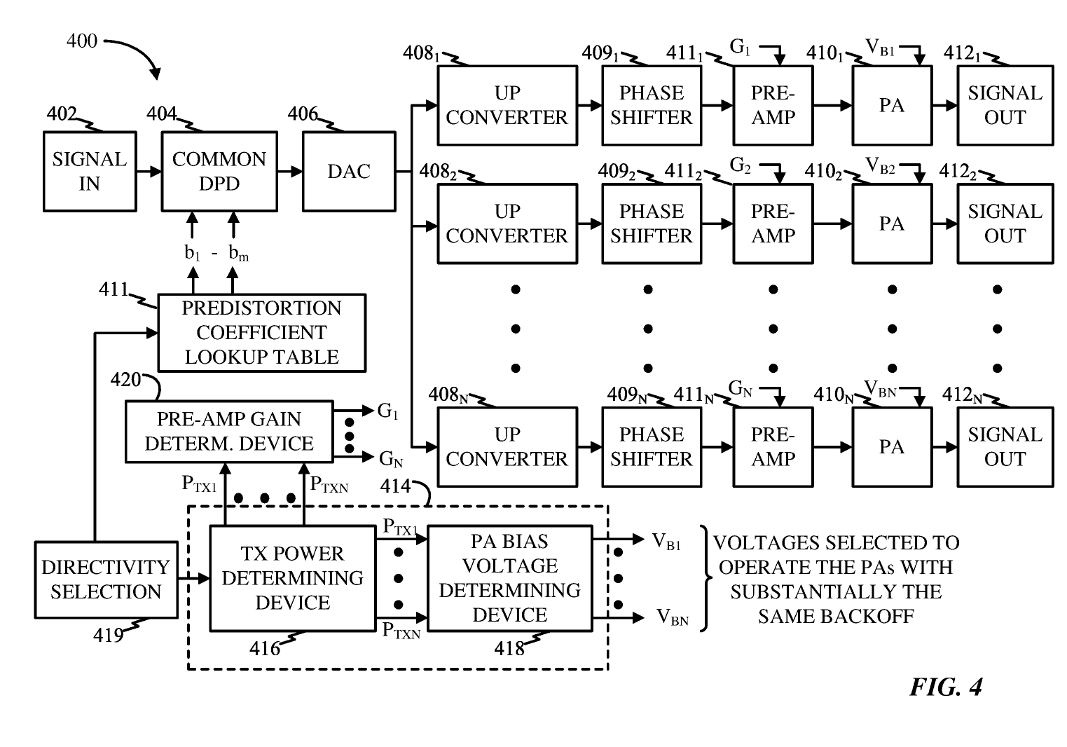

FIG. 4 is a more detailed block diagram of an exemplary transmitter 400 for use in a wireless device and configured in accordance with aspects of the disclosure, which illustrates additional components than in FIG. 3. The transmitter 400 includes a set of N transmit chains. Each transmit chain includes an upconverter (e.g., upconverters 408₁-408_{N}), a phase shifter (e.g., phase shifters 409₁-409_{N}), a pre-amplifier (e.g. pre-amp 411₁-411_{N}), a PA (e.g., PAs 410₁-410_{N}), and an output signal port (e.g., output signal ports 412₁-412_{N}). The pre-amp (or other PA controller) of each transmit chain controls the transmission power of the corresponding PA of the chain based on a variable gain signal, as discussed below). The PAs are again configured to have substantially the same characteristics (e.g. the same non-linearity profile, etc.) and are typically identical devices. As illustrated, the PAs 410₁-410_{N} receive bias voltages V_{B1} to V_{BN}, respectively, which can be used to set or select the saturation level of the PA. That is, by changing the bias, the saturation level can be changed. The transmitter 400 further includes a signal input port 402, a common DPD 404, and a DAC 406 common to all of the transmit chains. The transmitter 400 also includes a power amplifier controller 414 with a transmit power (or gain) determining device 416 and a PA bias voltage determining device 418. The power amplifier controller 414 receives a value representative of a selected directivity of the antenna array (not shown) from a directivity selection device or unit 419. The directivity value is again determined or set by other components of the wireless device to achieve desired beamforming to improve the transmission of a transmit signal towards a target receiving device (e.g., the device expected to receive the transmit signal)

Based on the directivity value, the transmit power (or gain) determining device 416 determines the appropriate output signal powers P_{TX1} to P_{TXN} of the transmit chains to achieve the selected directivity. The output power P_{TX1} to P_{TXN} values are provided to the PA bias voltage determining device 418, which then determines the appropriate bias voltages V_{B1} to V_{BN} for applying to the PAs 410₁-410_{N} to achieve the appropriate output powers while operating with substantially the same backoff. As shown, the output power P_{TX1} to P_{TXN} values are also applied to a pre-amp gain determining device 420 (or other suitable device), which provides variable gain signals G₁ . . . G_{N} that are applied to the pre-amps 411₁-411_{N} to facilitate power control. That is, the PA bias voltage determining device 418 and the pre-amp gain determining device 420 operate in parallel and both receive the same P_{TX1} to P_{TXN} values. (In FIG. 4, the pre-amp gain determining device 420 is shown separately from the power amplifier controller 414 but could be a component of the power amplifier controller 414.)

In an illustrative example, a transmitter with four (4) transmit chains (N=4) may be provided. An output power profile for the transmit chains, as determined by the transmit power (or gain) determining device 416, may include P_{TX1}=20 dbm, P_{TX2}=40 dbm, P_{TX3}=15 dbm, and P_{TX4}=5 dbm based on the selected directivity for the corresponding antenna array, with a selected backoff for all the chains set to 4 dB. The PA bias voltage determining device 418 then determines the particular bias voltages (V_{B1}-V_{B4}) for setting the PAs (310₁-410₄) so the PAs will provide the appropriate amount of power with the same backoff from saturation. In this particular example, respective saturation levels of 24 dBm, 44 dBm, 19 dBm, and 8 dBm, respectively, may be used.

The bias voltages (V_{B1}-V_{B4}) needed to achieve the respective saturation levels are then applied to the respective PAs (410₁-410₄) so that the PAs are operated at substantially the same backoff. So, in this example, the bias voltage (V_{B1}) for the first PA (310₁) is set so that the average power of the PA 410₁ is at 20 dbm with the saturation at 24 dbm, thus providing the 4 dbm backoff for that PA. The bias voltage (V_{B2}) for the second PA (310₂) is set so that the average power of the PA 410₂ is at 40 dbm with the saturation at 44 dbm, thus providing the same 4 dbm backoff. As explained above, since the same backoff is used for the PAs, the distortion of their respective output signals is substantially the same, allowing the use of the single common DPD 404. Particular coefficients for applying to the DPD 404 for a particular directionality are determined in advance using calibration procedures, described below.

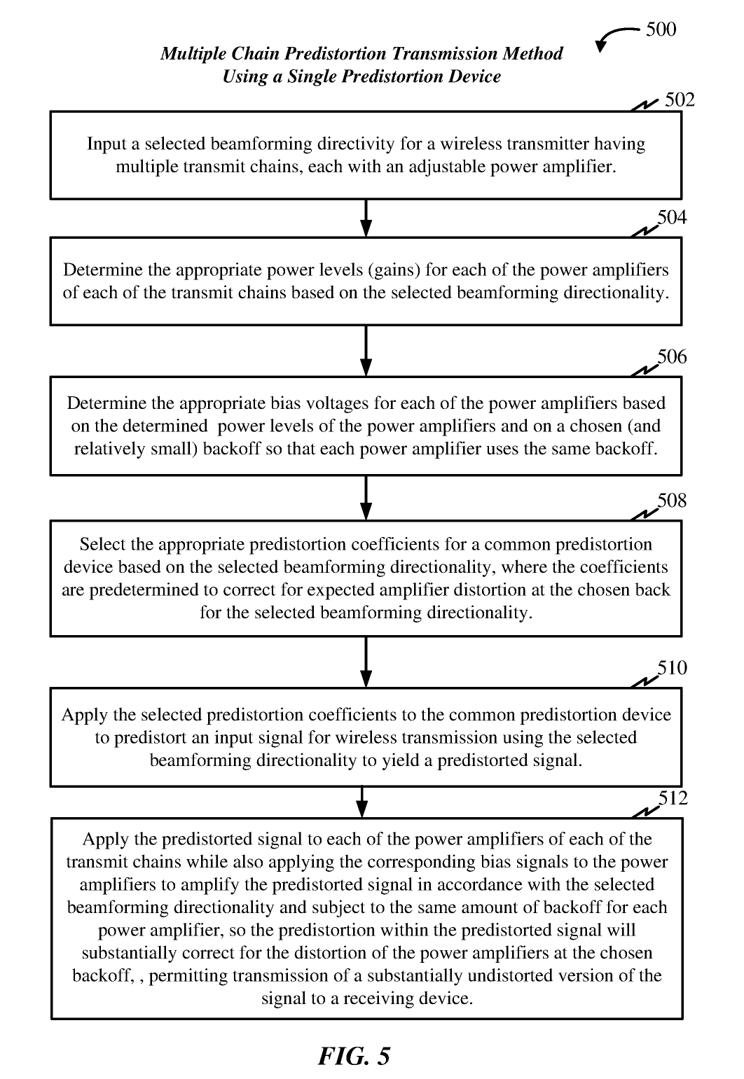

FIG. 5 illustrates a method 500 for transmitting signals using the transmitter of FIG. 3 or similarly equipped transmitters. Briefly, at 502, a selected beamforming directivity for a wireless transmitter having multiple transmit chains is input, where each of the transmit chains has an adjustable power amplifier. At 504, the appropriate power levels (gains) are determined for each of the power amplifiers of each of the transmit chains based on the selected beamforming directionality. At 506, the appropriate bias voltages are determined for each of the power amplifiers based on the determined power levels of the power amplifiers and on a chosen (and relatively small) backoff so that each power amplifier uses substantially the same backoff. At 508, the appropriate predistortion coefficients for a common predistortion device are selected (e.g. by table lookup) based on the selected beamforming directionality, where the coefficients are predetermined to correct for expected amplifier distortion at the chosen backoff for the selected beamforming directionality. At 510, the selected predistortion coefficients are applied to the common predistortion device to predistort an input signal for wireless transmission using the selected beamforming directionality to yield a predistorted signal. At 512, the predistorted signal is applied to each of the power amplifiers of each of the transmit chains while also applying the corresponding bias signals to the power amplifiers to amplify the predistorted signal in accordance with the selected beamforming directionality and subject to the same amount of backoff for each power amplifier. This allows the predistortion within the predistorted input signal to substantially correct for the distortion of the power amplifiers at the chosen backoff, permitting transmission of a substantially undistorted version of the signal to a receiving device.

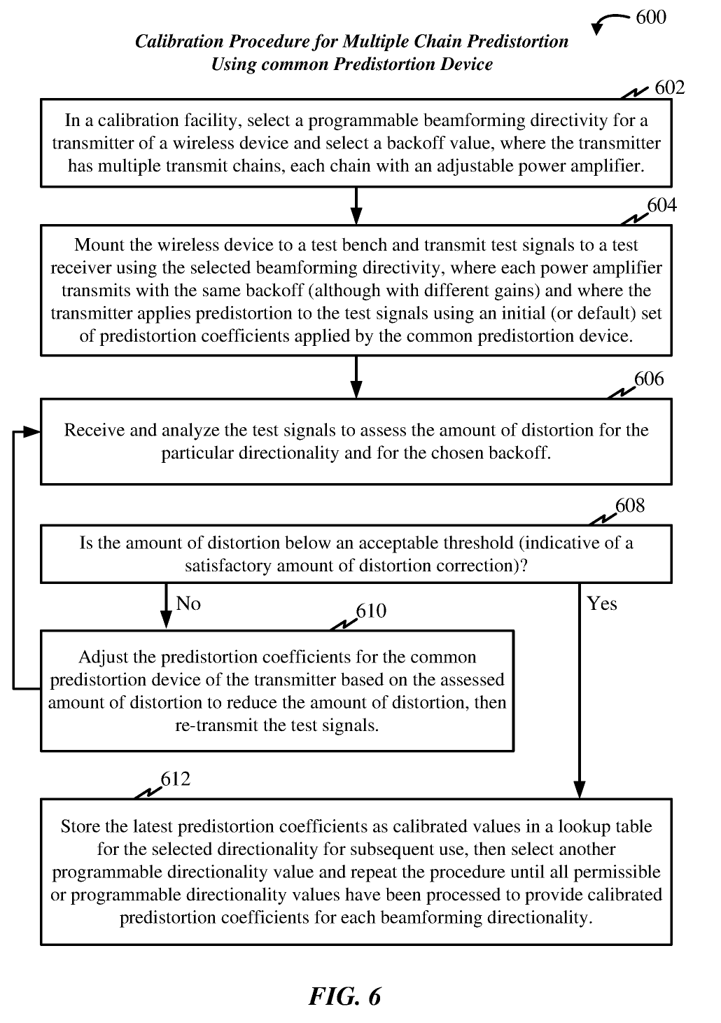

FIG. 6 summarizes an array-based calibration procedure or method 600 for calibrating predistortion coefficients for use with a transmitter having a common predistortion device. Briefly, at 602, in a factory or calibration facility, a programmable beamforming directivity is selected for a transmitter of a wireless device, where the transmitter has multiple transmit chains, each chain with an adjustable power amplifier. A backoff value is selected as well, which may be relatively small, e.g. 4 dbm. At 604, the wireless device is mounted to a test bench and test signals are transmitted to a test receiver using the selected beamforming directivity, where each power amplifier of the wireless device transmits with the same backoff (although with different gains) and where the transmitter applies predistortion to the test signals using an initial (or default) set of predistortion coefficients applied by the common predistortion device. At 606, the test signals are received and analyzed to assess the amount of distortion (such as EVM) for the particular directionality and for the chosen backoff.

If the amount of distortion is not yet below an acceptable threshold (indicative of a satisfactory amount of distortion correction for the overall transmission array), as determined at 608, processing proceeds to 610. At 610, the predistortion coefficients for the common predistortion device of the transmitter are adjusted based on the assessed amount of distortion to reduce the amount of distortion, and the test signals are then re-transmitted. On the other hand, if the amount of distortion is below the acceptable threshold, as determined at 608, processing proceeds to 612. At 612, the latest (i.e. the current set of) predistortion coefficients are stored as calibrated values in a lookup table for the selected directionality for subsequent use by the wireless device. Also, at 612, another programmable directionality value is selected and the procedure is repeated (beginning again at 602) until all permissible or programmable directionality values have been processed to provide calibrated predistortion coefficients for each programmable of permissible beamforming directionality for the overall transmission array. Using this factory calibration technique, a form of feedback is thereby used, but the feedback is from the test receiver back to the DPD module of the transmitter, rather than from the output of an individual PA of an individual transmit chain back to the DPD module.

FIG. 6 thus illustrates an exemplary calibration procedure for an open loop transmitter. Other calibration procedures may be used that employ more sophisticated techniques that take into account additional criteria such as temperature. In still other calibration examples, the calibration system may set the distortion correction based on the highest power transmit chain. For example, a single DPD may be designed/calibrated to provide distortion correction based on the backoff required for the transmit chain with the maximum transmission power for a particular directionality, i.e. while disregarding the distortion that might arise from the other PAs of the transmitter, since they will be operating at lower power and hence will provide less distortion. This may depend on the total amount of distortion that the overall wireless communication system tolerates.

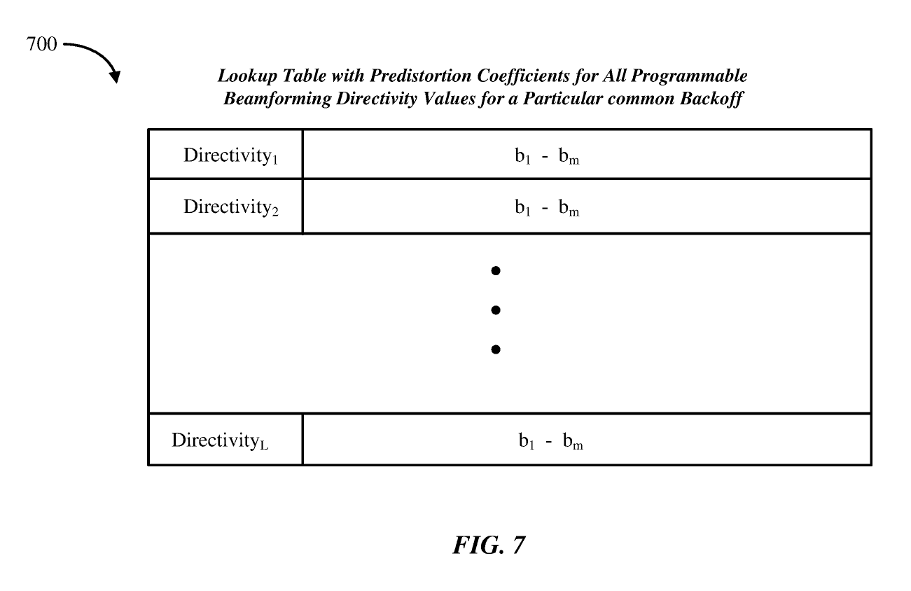

FIG. 7 illustrates an exemplary lookup table 700 that stores predistortion coefficients for a different beamforming directivity values for a particular common backoff (that was found to be suitable). Briefly, the lookup table 700 includes a separate row for each of a set of permissible or programmable directivity values where, in this example, there are L such values (Directivity₁-Directivity_{L}). Each row includes the predistortion coefficients (b₁ to bₘ) for that particular directivity (as determined using the calibration procedure of FIG. 5 or other suitable procedures). The table is stored in the wireless device for use by the common predistortion component of the device transmitter. As noted, the predistortion coefficients (b₁ to bₘ) of the lookup table are for use with a particular common backoff. The lookup table can include additional rows to permit the predistortion coefficients for different common backoff values to be stored as well.

As noted, although the examples herein use open loop DPD, at least some of the techniques described herein are also applicable to closed loop configurations where the output RF signals from each PA are sampled and fed back to the common DPD module (as downconverted digital signals) for use in adaptively adjusting the DPD. Note that for a closed loop configuration, factory calibration is not typically performed, since the predistortion coefficients are instead adjusted while the transmitter is in use. It should be understood that for an implementation having a common DPD with a large number of transmit chains (e.g. perhaps hundreds of such chains), identifying and maintaining optimal predistortion coefficients via feedback from the individual PAs of the many transmit chains back to the common DPD may have practical challenges and may be computationally intensive. Distortion feedback information may also be relayed back from a receive device to a transmit device for use by the DPD module of the transmitter, although this would likely require changing the overall communications protocol to permit the receive device to send the distortion feedback information.

### An Illustrative Example of a Wireless Communication System

The techniques described herein may be used for various broadband wireless communication systems, including communication systems that are based on a single-carrier or an orthogonal multiplexing scheme. Examples of such communication systems include Spatial Division Multiple Access (SDMA), Time Division Multiple Access (TDMA), Orthogonal Frequency Division Multiple Access (OFDMA) systems, Single-Carrier Frequency Division Multiple Access (SC-FDMA) systems, and so forth. An SDMA system may utilize sufficiently different directions to simultaneously transmit data belonging to multiple user terminals. A TDMA system may allow multiple user terminals to share the same frequency channel by dividing the transmission signal into different time slots, each time slot being assigned to different user terminal. An OFDMA system utilizes orthogonal frequency division multiplexing (OFDM), which is a modulation technique that partitions the overall system bandwidth into multiple orthogonal sub-carriers. These sub-carriers may also be called tones, bins, etc. With OFDM, each sub-carrier may be independently modulated with data. An SC-FDMA system may utilize interleaved FDMA (IFDMA) to transmit on sub-carriers that are distributed across the system bandwidth, localized FDMA (LFDMA) to transmit on a block of adjacent sub-carriers, or enhanced FDMA (EFDMA) to transmit on multiple blocks of adjacent sub-carriers. In general, modulation symbols are sent in the frequency domain with OFDM and in the time domain with SC-FDMA.

The teachings herein may be incorporated into (e.g., implemented within or performed by) a variety of wired or wireless apparatuses (e.g., nodes). In some aspects, a wireless node implemented in accordance with the teachings herein may comprise an access point or an access terminal.

An access point (“AP”) may comprise, be implemented as, or known as a Node B, Radio Network Controller (“RNC”), evolved Node B (eNB), Base Station Controller (“BSC”), Base Transceiver Station (“BTS”), Base Station (“BS”), Transceiver Function (“TF”), Radio Router, Radio Transceiver, Basic Service Set (“BSS”), Extended Service Set (“ESS”), Radio Base Station (“RBS”), or some other terminology.

An access terminal (“AT”) may comprise, be implemented as, or known as a subscriber station, a subscriber unit, a mobile station (MS), a remote station, a remote terminal, a user terminal (UT), a user agent, a user device, user equipment (UE), a user station, or some other terminology. In some implementations, an access terminal may comprise a cellular telephone, a cordless telephone, a Session Initiation Protocol (“SIP”) phone, a wireless local loop (“WLL”) station, a personal digital assistant (“PDA”), a handheld device having wireless connection capability, a Station (“STA”), or some other suitable processing device connected to a wireless modem. Accordingly, one or more aspects taught herein may be incorporated into a phone (e.g., a cellular phone or smart phone), a computer (e.g., a laptop), a tablet, a portable communication device, a portable computing device (e.g., a personal data assistant), an entertainment device (e.g., a music or video device, or a satellite radio), a global positioning system (GPS) device, or any other suitable device that is configured to communicate via a wireless or wired medium. In some aspects, the node is a wireless node. Such wireless node may provide, for example, connectivity for or to a network (e.g., a wide area network such as the Internet or a cellular network) via a wired or wireless communication link.

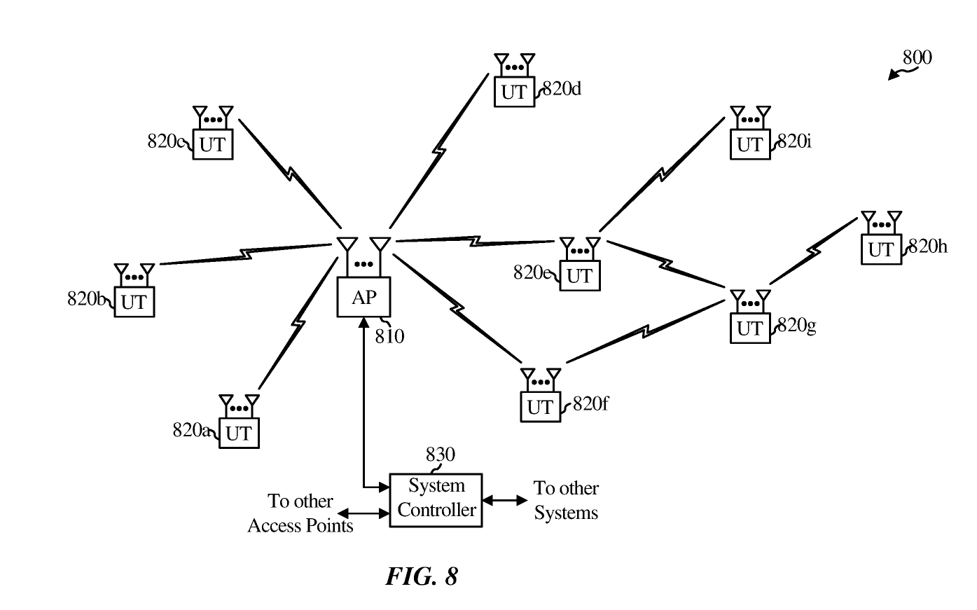

FIG. 8 illustrates a multiple-access multiple-input multiple-output (MIMO) system 800 with access points and user terminals in which aspects of the present disclosure may be practiced. Additionally or alternatively, aspects of the present disclosure may be implemented within beamforming systems. For the MIMO example of FIG. 8, access point 810 or user terminals 820 may include transmitters with the common DPD device configured as described above. For simplicity, only one access point 810 is shown in FIG. 8. An access point is generally a fixed station that communicates with the user terminals and may also be referred to as a base station or some other terminology. A user terminal may be fixed or mobile and may also be referred to as a mobile station, a wireless device, or some other terminology. Access point 810 may communicate with one or more user terminals 820 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 830 couples to and provides coordination and control for the access points.

While portions of the following disclosure will describe user terminals 820 capable of communicating via Spatial Division Multiple Access (SDMA), for certain aspects, the user terminals 820 may also include some user terminals that do not support SDMA. Thus, for such aspects, an AP 810 may be configured to communicate with both SDMA and non-SDMA user terminals. This approach may conveniently allow older versions of user terminals (“legacy” stations) to remain deployed in an enterprise, extending their useful lifetime, while allowing newer SDMA user terminals to be introduced as deemed appropriate.

The SDMA system may be a time division duplex (TDD) system or a frequency division duplex (FDD) system. For a TDD system, the downlink and uplink share the same frequency band. For an FDD system, the downlink and uplink use different frequency bands. MIMO system 800 may also utilize a single carrier or multiple carriers for transmission. Each user terminal may be equipped with a single antenna (e.g., in order to keep costs down) or multiple antennas (e.g., where the additional cost can be supported). The system 800 may also be a TDMA system if the user terminals 820 share the same frequency channel by dividing transmission/reception into different time slots, each time slot being assigned to different user terminal 820.

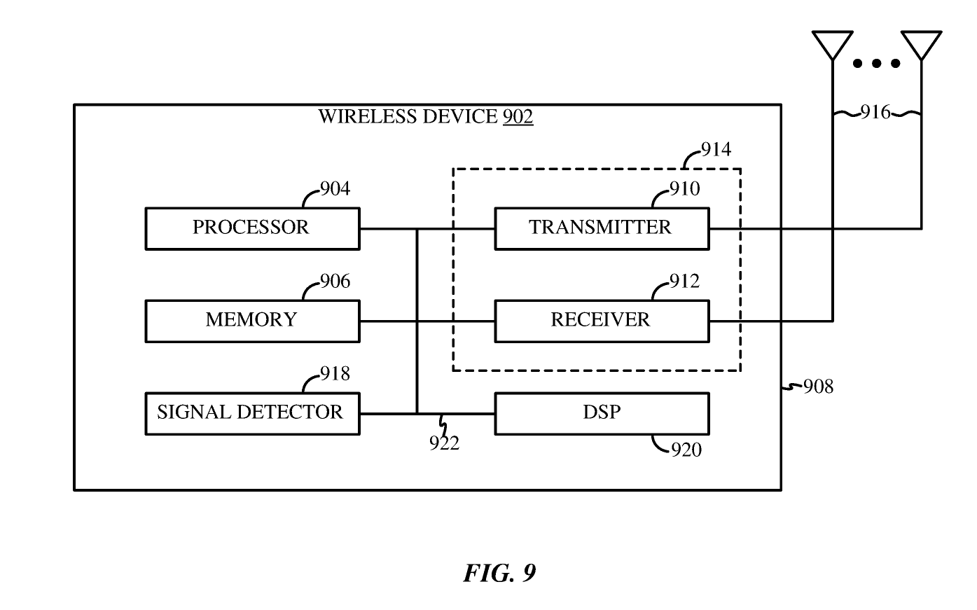

FIG. 9 illustrates various components that may be utilized in a wireless device 902 in which aspects of the present disclosure may be practiced and that may be employed within the MIMO system 1000. The wireless device 902 is an example of a device that may be configured to implement the various methods described herein. The wireless device 902 may be an access point 810 or a user terminal 820.

The wireless device 902 may include a processor 904 which controls operation of the wireless device 902. The processor 904 may also be referred to as a central processing unit (CPU). Memory 906, which may include both read-only memory (ROM) and random access memory (RAM), provides instructions and data to the processor 904. A portion of the memory 906 may also include non-volatile random access memory (NVRAM). The processor 904 typically performs logical and arithmetic operations based on program instructions stored within the memory 906. The instructions in the memory 906 may be executable to implement the methods described herein. Processor 904 may, for example, direct all or some of the operations of the various flowcharts of the drawings to implement DPD or other features.

The wireless device 902 may also include a housing 908 that may include a transmitter 910 and a receiver 912 to allow transmission and reception of data between the wireless device 902 and a remote location. The transmitter 910 and receiver 912 may be combined into a transceiver 914. A single or a plurality of transmit antennas 916 or other transmitters may be attached to the housing 908 and electrically coupled to the transceiver 914. The wireless device 902 may also include (not shown) multiple transmitters, multiple receivers, and multiple transceivers. The transmitter 90 may be equipped or configured as described above to perform the operations of the various flowcharts.

The wireless device 902 may also include a signal detector 918 that may be used in an effort to detect and quantify the level of signals received by the transceiver 914. The signal detector 918 may detect such signals as total energy, energy per subcarrier per symbol, power spectral density and other signals. The wireless device 902 may also include a digital signal processor (DSP) 920 for use in processing signals. The various components of the wireless device 902 may be coupled together by a bus system 922, which may include a power bus, a control signal bus, and a status signal bus in addition to a data bus.

### Summary of Exemplary Operations and Apparatus

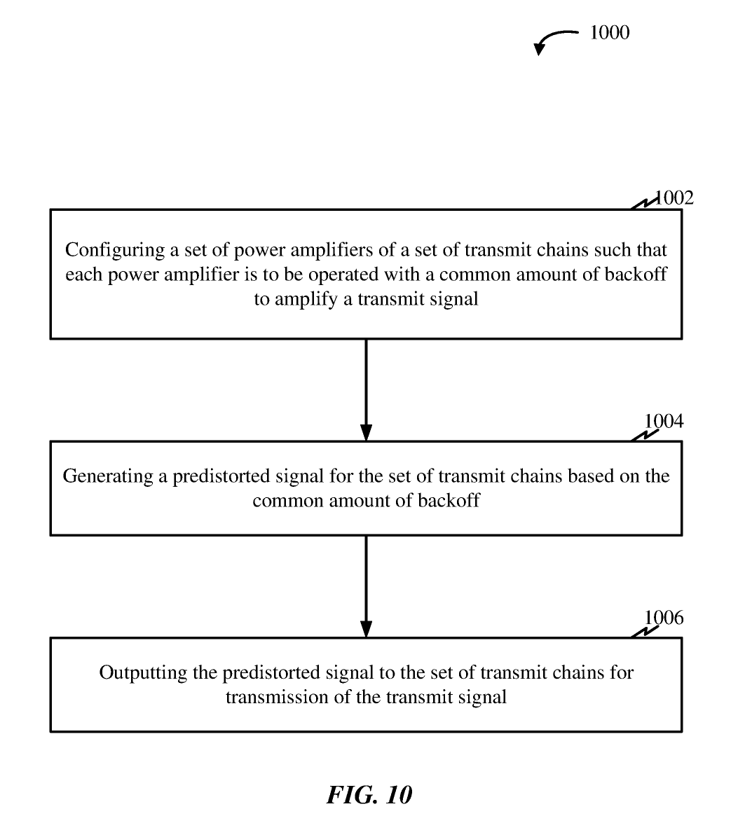

FIG. 10 summarizes an exemplary method 1000 that may be performed by an apparatus for applying predistortion to a signal, in accordance with certain aspects of the present disclosure, where the apparatus is for use with a wireless communications device having a plurality of transmit chains, each with a separate power amplifier. The method 1000 comprises configuring a set of power amplifiers of a set of transmit chains such that each power amplifier is to be operated with a common amount of backoff to amplify a transmit signal (block 1002). The method 1000 further comprises generating a predistorted signal for the set of transmit chains based on the common amount of backoff (block 1004). Additionally, the method 1000 comprises outputting the predistorted signal to the set of transmit chains for transmission of the transmit signal (block 1006). Further details of the exemplary method 1000 are discussed above, particularly with reference to FIGS. 3-5.

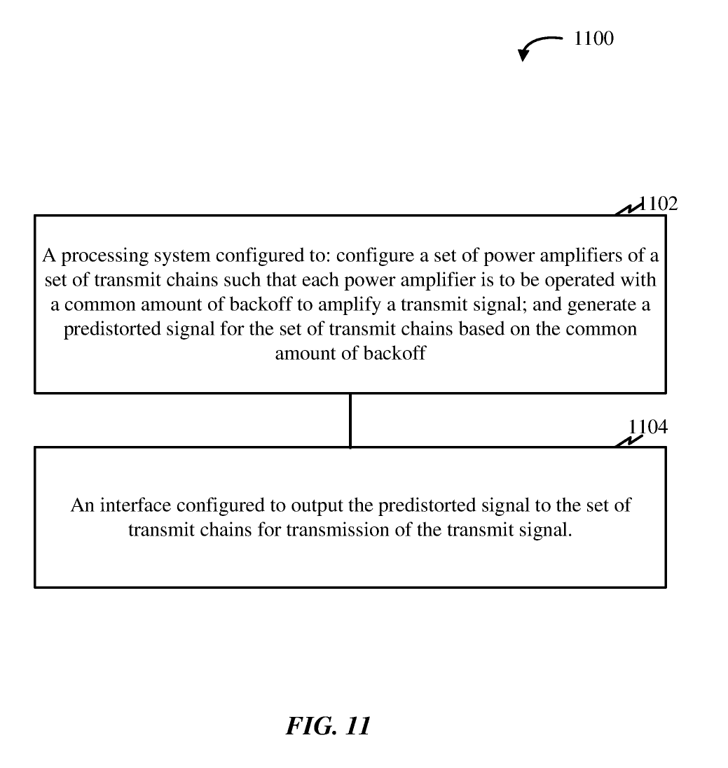

FIG. 11 summarizes an exemplary apparatus or device 1100 having components that may be used to apply predistortion to a signal, in accordance with certain aspects of the present disclosure. Briefly, the apparatus 1100 includes a processing system 1102 configured to: configure a set of power amplifiers of a set of transmit chains such that each power amplifier is to be operated with a common amount of backoff to amplify a transmit signal; and generate a predistorted signal for the set of transmit chains based on the common amount of backoff. The apparatus further includes an interface 1104 configured to output the predistorted signal to the set of transmit chains for transmission of the transmit signal. Further details of exemplary apparatus 1100 are discussed above, particularly with reference to FIGS. 3-5.

The various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

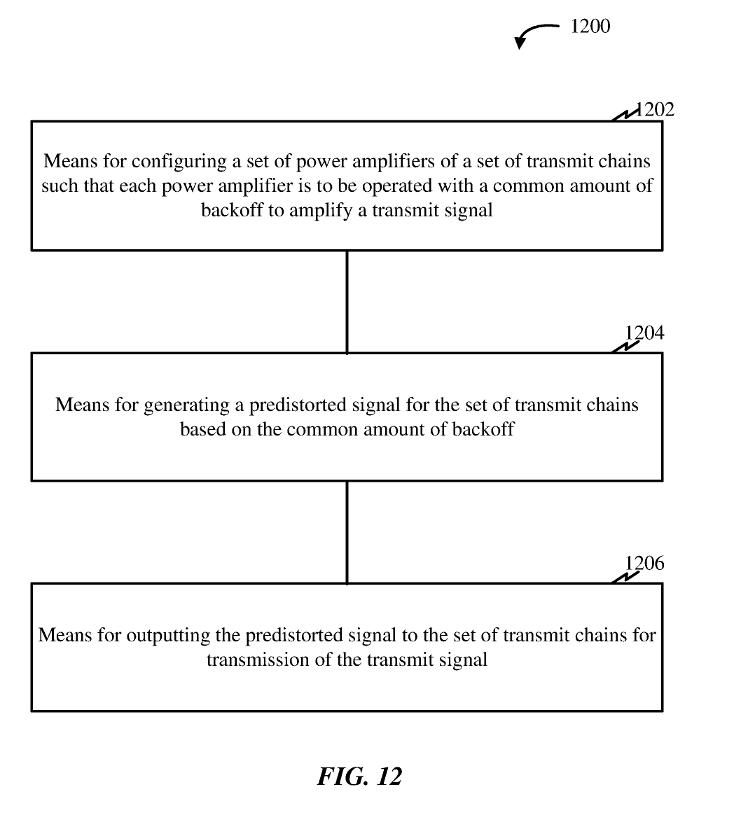

For example, the individual operations of the method 1000 of FIG. 10 may correspond to individual means of an apparatus 1200 illustrated in FIG. 12, which in turn may correspond with one or more devices or components illustrated in FIGS. 3 -4. For instance, the apparatus 1200 includes means 1202 for configuring a set of power amplifiers of a set of transmit chains such that each power amplifier is to be operated with a common amount of backoff to amplify a transmit signal. Such means 1202 includes, for example, at least one of the processor 904, the DSP 920, the power amplifier controller 308, or the PA bias voltage determining device 418. The apparatus 1200 further includes means 1204 for generating a predistorted signal for the set of transmit chains based on the common amount of backoff. Such means 1204 includes, for example, at least one of the processor 904, the DSP 920, the common predistortion device 306, or the common DPD 411 including the predistortion coefficient lookup table. Additionally, the apparatus 1200 includes means 1206 for outputting the predistorted signal to the set of transmit chains for transmission of the transmit signal. Such means 1206 includes, for example, at least one of the bus system 922, the output of the common predistortion device 306, or the output of the common DPD 404.

Regarding other means, means for determining a set of bias voltages for the set of power amplifiers such that each power amplifier is configured to be operated with the common amount of backoff includes, for example, at least one of the processor 904, the DSP 920, the power amplifier controller 308, or the PA bias voltage determining device 418. Means for applying the set of bias voltages to the set of power amplifiers includes, for example, at least one of the bus system 922, the output of the power amplifier controller 308, or the output of the PA bias voltage determining device 418.

Regarding additional means, means for selecting a directivity for transmission of the transmit signal based on a direction towards a device expected to receive the transmit signal includes, for example, at least one of the processor 904, the DSP 920, or the directivity selection device 419. Means for determining the set of bias voltages based on the selected directivity for transmission of the transmit signal includes, for example, at least one of the processor 904, the DSP 920, the power amplifier controller 308, or the PA bias voltage determining device 418. Means for configuring a set of gains of a set preamplifiers in the set of transmit chains based on the selected directivity includes, for example, at least one of the processor 904, the DSP 920, or the pre-amplifier gain determining device 420.

Regarding additional means, means for selecting a directivity for transmission of the transmit signal includes, for example, at least one of processor 904, the DSP 920, or the directivity selection device 419. Means for determining a set of output signal powers for the set of transmit chains to achieve the selected directivity for transmission of the transmit signal includes, for example, at least one of the processor 904, the DSP 920, the power amplifier controller 308, or the transmit power determining device 416. Means for determining a set of bias voltages for the set of power amplifiers based on the set of output signal powers and the common amount of backoff, respectively, includes, for example, at least one of the processor 904, the DSP 920, the power amplifier controller 308, or the PA bias voltage determining device 418. Means for applying the set of bias voltages to the set of power amplifiers, respectively, includes, for example, at least one of bus system 922, the output of the power amplifier controller 308, or the output of the PA bias voltage determining device 418.

Regarding further means, means for determining a set of predistortion coefficients based on the common amount of backoff includes, for example, at least one of the processor 904, the DSP 920, the predistortion coefficient lookup table 310, or the predistortion coefficient lookup table 411. Means for generating the predistorted signal based on the set of predistortion coefficients includes, for example, at least one of the processor 904, the DSP 920, the common predistortion device 306, or the common DPD 404. Means for determining the set of predistortion coefficients based on a selected directivity for transmission of the transmit signal includes, for example, at least one of the processor 904, the DSP 920, the common predistortion device 306, or the common DPD 404. Means for configuring a set of gains of a set preamplifiers in the set of transmit chains based on the selected directivity includes, for example, at least one of the processor 904, the DSP 920, or the pre-amplifier gain determining device 420.

These are just some examples of particular means-plus-function components described herein and other suitable devices or components may be used.

In some examples, a non-transitory computer readable medium may be provided that has instructions stored thereon for controlling a transmitter device, such as the transmitter device of FIG. 3. The instructions may serve to control the operation of a control processor (such as processor 904 of FIG. 9) to control a transmitter (such as the transmitter 910 of FIG. 9).

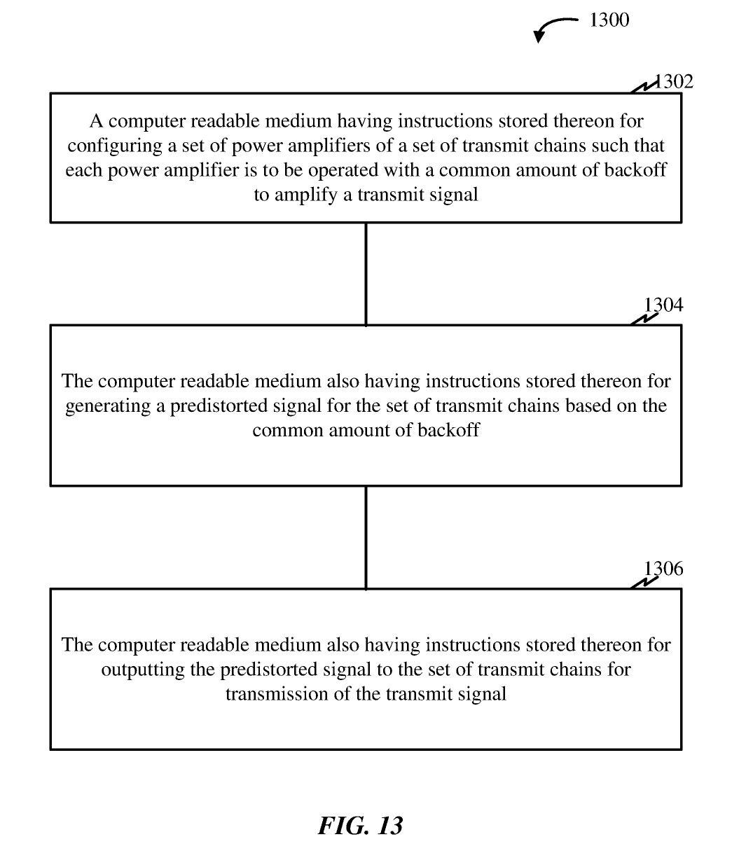

FIG. 13 illustrates exemplary non-transitory computer readable media and their instructions. Briefly, a computer readable medium 1300 may be provided having instructions 1302 stored thereon for configuring a set of power amplifiers of a set of transmit chains such that each power amplifier is to be operated with a common amount of backoff to amplify a transmit signal. The computer readable medium may also have instructions 1304 stored thereon for generating a predistorted signal for the set of transmit chains based on the common amount of backoff. And, the computer readable medium may also have instructions 1306 stored thereon outputting the predistorted signal to the set of transmit chains for transmission of the transmit signal.

These are just some examples of instructions that may be stored in a non-transitory computer readable medium and used to control one or more components or devices. Generally speaking, any of the functions or method operations described herein may have a corresponding set of instructions for use in controlling, or at least activating or deactivating, the respective device or component.

As used herein, the term “generating” encompasses a wide variety of actions. For example, “generating” may include calculating, causing, computing, creating, determining, processing, deriving, investigating, making, producing, providing, giving rise to, leading to, resulting in, looking up (e.g., looking up in a table, a database or another data structure), ascertaining and the like. Also, “generating” may include receiving (e.g., receiving information), accessing (e.g., accessing data in a memory) and the like. Also, “generating” may include resolving, selecting, choosing, establishing and the like.

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like. Also, “determining” may include measuring, estimating and the like.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any such list including multiples of the same members (e.g., any lists that include aa, bb, or cc).

The various illustrative logical blocks, modules and circuits described in connection with the present disclosure may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in any form of storage medium that is known in the art. Some examples of storage media that may be used include random access memory (RAM), read only memory (ROM), flash memory, EPROM memory, EEPROM memory, registers, a hard disk, a removable disk, a CD-ROM and so forth. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the PHY layer. In the case of a user terminal 120 (see FIG. 1), a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processor may be responsible for managing the bus and general processing, including the execution of software stored on the machine-readable media. The processor may be implemented with one or more general-purpose and/or special-purpose processors. Examples include microprocessors, microcontrollers, DSP processors, and other circuitry that can execute software. Software shall be construed broadly to mean instructions, data, or any combination thereof, whether referred to as software, firmware, middleware, microcode, hardware description language, or otherwise. Machine-readable media may include, by way of example, RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. The machine-readable media may be embodied in a computer-program product. The computer-program product may comprise packaging materials.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the wireless node, all which may be accessed by the processor through the bus interface. Alternatively, or in addition, the machine-readable media, or any portion thereof, may be integrated into the processor, such as the case may be with cache and/or general register files.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC (Application Specific Integrated Circuit) with the processor, the bus interface, the user interface in the case of an access terminal), supporting circuitry, and at least a portion of the machine-readable media integrated into a single chip, or with one or more FPGAs (Field Programmable Gate Arrays), PLDs (Programmable Logic Devices), controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

The machine-readable media may comprise a number of software modules. The software modules include instructions that, when executed by the processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a general register file for execution by the processor. When referring to the functionality of a software module below, it will be understood that such functionality is implemented by the processor when executing instructions from that software module.

If implemented in software, the functions may be stored or transmitted over as one or more instructions or code on a computer-readable medium. Computer-readable media include both computer storage media and communication media including any medium that facilitates transfer of a computer program from one place to another. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared (IR), radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk, and Blu-ray® disc where disks usually reproduce data magnetically, while discs reproduce data optically with lasers. Thus, in some aspects computer-readable media may comprise non-transitory computer-readable media (e.g., tangible media). In addition, for other aspects computer-readable media may comprise transitory computer-readable media (e.g., a signal). Combinations of the above should also be included within the scope of computer-readable media.

Thus, certain aspects may comprise a computer program product for performing the operations presented herein. For example, such a computer program product may comprise a computer-readable medium having instructions stored (and/or encoded) thereon, the instructions being executable by one or more processors to perform the operations described herein. For certain aspects, the computer program product may include packaging material.

Further, it should be appreciated that modules and/or other appropriate means for performing the methods and techniques described herein can be downloaded and/or otherwise obtained by a user terminal and/or base station as applicable. For example, such a device can be coupled to a server to facilitate the transfer of means for performing the methods described herein. Alternatively, various methods described herein can be provided via storage means (e.g., RAM, ROM, a physical storage medium such as a compact disc (CD) or floppy disk, etc.), such that a user terminal and/or base station can obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes and variations may be made in the arrangement, operation and details of the methods and apparatus described above without departing from the scope of the claims.

1. An apparatus for wireless communications, comprising:
a processing system configured to:
predistort a transmit signal; and
configure a set of distinct bias voltages for a set of power amplifiers for amplification of the predistorted transmit signal, said power amplifiers having a common amount of backoff; and
an interface configured to output the amplified predistorted transmit signal for transmission.

2. The apparatus of claim 1, wherein the processing system is configured to:
determine the set of distinct bias voltages for the set of power amplifiers; and
cause the set of distinct bias voltages to be applied to the set of power amplifiers, respectively.

3. The apparatus of claim 2, wherein the processing system is configured to select a directivity for transmission of the amplified predistorted transmit signal based on a direction towards a device expected to receive the amplified predistorted transmit signal; and determine the set of distinct bias voltages based on the selected directivity.

4. The apparatus of claim 3, wherein the processing system is further configured to configure a set of gains of a set preamplifiers based on the selected directivity, wherein the set of preamplifiers control a power level of the amplified predistorted transmit signal.

5. The apparatus of claim 1, wherein the processing system is configured to:
select a directivity for transmission of the amplified predistorted transmit signal;
determine a set of output signal powers for the set of power amplifiers to achieve the selected directivity for transmission of the amplified predistorted transmit signal;
determine the set of distinct bias voltages for the set of power amplifiers based on the set of output signal powers and the common amount of backoff; and
cause the set of distinct bias voltages to be applied to the set of power amplifiers.

6. The apparatus of claim 1, wherein the processing system is configured to:
determine a set of predistortion coefficients based on the common amount of backoff,
wherein the transmit signal is predistorted based on the set of predistortion coefficients.

7. The apparatus of claim 6, wherein the processing system is configured to select a directivity for transmission of the amplified predistorted transmit signal and wherein determining the set of predistortion coefficients is based on the selected directivity.

8. A method for wireless communications, comprising:
predistorting a transmit signal;
configuring a set of distinct bias voltages for a set of power amplifiers for amplification of the predistorted transmit signal, said power amplifiers having a common amount of backoff; and
outputting the amplified predistorted transmit signal for transmission.

9. The method of claim 8, wherein configuring the set of power amplifiers comprises:
determining the set of distinct bias voltages for the set of power amplifiers; and
applying the set of distinct bias voltages to the set of power amplifiers, respectively.

10. The method of claim 9, further comprising selecting a directivity for transmission of the amplified predistorted transmit signal based on a direction towards a device expected to receive the amplified predistorted transmit signal; and wherein determining the set of distinct bias voltages is based on the selected directivity.

11. The method of claim 10, further comprising configuring a set of gains of a set preamplifiers based on the selected directivity, wherein the set of preamplifiers control a power level of the amplified predistorted transmit signal.

12. The method of claim 8, wherein configuring the set of power amplifiers comprises:
selecting a directivity for transmission of the amplified predistorted transmit signal;
determining a set of output signal powers for the set of power amplifiers to achieve a selected directivity for transmission of the amplified predistorted transmit signal;
determining the set of distinct bias voltages for the set of power amplifiers based on the set of output signal powers and the common amount of backoff; and
applying the set of bias distinct voltages to the set of power amplifiers.

13. The method of claim 8, wherein generating the predistorted transmit signal comprises:
determining a set of predistortion coefficients based on the common amount of backoff,
wherein predistorting the transmit signal is based on the set of predistortion coefficients.

14. The method of claim 13, further comprising selecting a directivity for transmission of the amplified predistorted transmit signal and wherein determining the set of predistortion coefficients is based on the selected directivity.

15-22. (canceled)

23. A wireless node, comprising:
a processing system configured to:
predistort a transmit signal; and
configure a set of distinct bias voltages for a set of power amplifiers for amplification of the predistorted transmit signal, said power amplifiers having a common amount of backoff; and
a transmitter is configured to
transmit the amplified predistorted transmit signal.

24. (canceled)

25. The wireless node of claim 23, further comprising:
an upconverter and a phase shifter configured to frequency upconvert and phase shift the predistorted transmit signal prior to amplification by the set of power amplifiers.

26. The wireless node of claim 23, wherein the transmitter includes a digital-to-analog converter (DAC) configured to convert the predistorted transmit signal from a digital format to an analog format.
